(19) United States
(12) Patent Application Publication
(10) Pub. No.: US 2025/0076755 A1
(43) Pub. Date: Mar. 6, 2025

(54) ORGANOTIN PHOTORESIST COMPOSITION FOR PHOTOLITHOGRAPHY PATTERNING

(71) Applicant: Feng Lu, Irvine, CA (US)

(72) Inventor: Feng Lu, Irvine, CA (US)

(21) Appl. No.: 18/812,202

(22) Filed: Aug. 22, 2024

Related U.S. Application Data
(60) Provisional application No. 63/535,678, filed on Aug. 31, 2023.

(51) Int. Cl. G03F 7/004; G03F 7/16

(52) U.S. Cl. CPC G03F 7/0042; G03F 7/0048; G03F 7/16

(57) ABSTRACT

An organotin photoresist composition for photolithography patterning is described, wherein organotin photoresist composition comprises a (stannocenyl oxide) tin compound, a solvent, and/or an additive. (Stannocenyl oxide) tin compound comprises cyclopentadienyl C₅H₅ group, or substituted cyclopentadienyl C₅H₄R, C₅H₃R₂, C₅H₂R₃, C₅HR₄, or C₅R₅ group. A method for photolithography patterning comprises depositing (stannocenyl oxide)tin compound photoresist composition over a substrate to form a photoresist layer; exposing the (stannocenyl oxide)tin photoresist layer to actinic radiation to form a latent pattern; and developing the latent pattern by applying a developer to remove the unexposed or exposed portion of photoresists to form a photolithography pattern.

### CROSS PEFERENCE TO RELATED APPLICATIONS

This application claims priority to U.S. provisional patent application No. 63/535,678 filed on Aug. 31, 2023 to Lu, entitled “Organotin photoresist composition for photolithography patterning”, of which is entirely incorporated herein by reference.

### FIELD OF INVENTION

The present invention relates to organotin photoresist composition for photolithography patterning, wherein organotin photoresist composition comprises a (stannocenyl oxide)tin compound, a solvent, and/or an additive. (Stannocenyl oxide)tin compound comprises cyclopentadienyl C₅H₅ group, or substituted cyclopentadienyl C₅H₄R, C₅H₃R₂, C₅H₂R₃, C₅HR₄, or C₅R₅ group.

### BACKGROUND

With the development of the semiconductor industry, nanoscale patterns have been in pursuit of higher devices density, higher performance, and lower costs. Reducing semiconductor feature size has become a grand challenge. Photolithography has been applied for creating microelectronic patterns over decades. Extreme ultraviolet (EUV) lithography is under development for mass production of smaller semiconductor devices feature size and increasement of devise density on a semiconductor wafer. EUV lithography is a pattern-forming technology using wavelength of 13.5 nm as an exposure light source to manufacture high-performance integrated circuits containing high-density structures patterned with nanometer scale. The application of EUV lithography can make extremely fine pattern with smaller width as equal to or less than 7 nm. Therefore, EUV lithography becomes one significant tool and technology for manufacturing next generation semiconductor devices.

In order to improve EUV lithography for smaller level, wafer exposure throughput can be improved through increased exposure power or increased photoresist sensitivity. Photoresists are radiation sensitive materials upon irradiation with relevant chemical transformation occurs in the exposed region, which would result in different properties between the exposed and unexposed regions. The properties of EUV photoresist, such as resolution, sensitivity, line edge roughness (LER), line width roughness (LWR), etch resistance and ability to form thinner layer are important in photolithography.

Organometallic compounds have high ultraviolet light adsorption because metals have high adsorption capacity of ultraviolet radiation with various carbon-metal (C—M) bond dissociation energy (BDE), and then can be used as photoresists and/or the precursors for photolithography at smaller level (e.g., <7 nm), which is of great interests for radiation lithography. Among those promising advanced materials, particularly organometallic tin (organotin) compounds can provide photoresist patterning with significant advantages, such as improved resolution, sensitivity, etch resistance, and lower line width/edge roughness without pattern collapse because of strong EUV radiation adsorption of tin, which have been demonstrated.

Organotin compounds have been demonstrated as EUV photoresists, which provide promising approach for the development of further smaller features such as <7 nm. Organotin photoresist composition comprises a (stannocenyl oxide)tin compound, a solvent, and/or additive, wherein cyclopentadienyl includes cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers, with improved resolution sensitivity, etch resistance, and lower line width/edge roughness without pattern collapse for photolithography patterning.

### SUMMARY

In a first aspect, the present invention pertains to organotin photoresist composition for photolithography patterning, wherein organotin photoresist comprises (stannocenyl oxide)tin compounds. The present invention is to provide improved resolution sensitivity, etch resistance, and lower line width/edge roughness without pattern collapse for photolithography patterning. The organotin photoresist composition comprises a (stannocenyl oxide)tin compound, a solvent, and/or an additive. The additive is organic molecule, including organic thiol, organic alcohol, organic amine, organic amide, organic carboxylic acid, organic phosphine, organic phosphine oxide, or organic phosphonic acid. In addition, (stannocenyl oxide)tin compounds also may be used as precursors for the preparation of organotin photoresists, or photoresist compositions.

In another aspect, stannocenyl oxide group comprises cyclopentadienyl C₅H₅ group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

Stannocenyl oxide includes hapticity of η¹, η², η³, η⁴, or η⁵ of isomers.

In a further aspect, the invention pertains to radiation sensitive (stannocenyl oxide)tin compound photoresists, wherein (stannocenyl oxide)tin compound is one or more selected from the group of Chemical Formulas (1)-(8) as below:

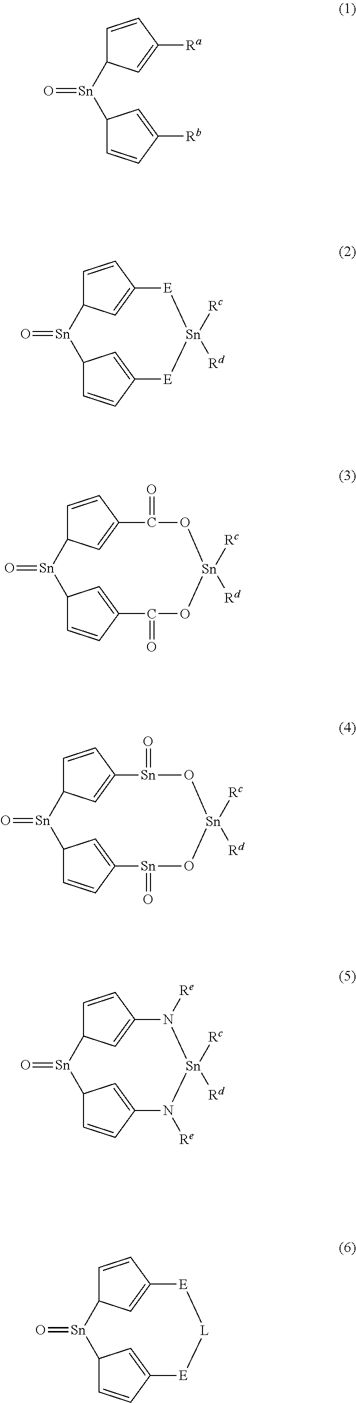

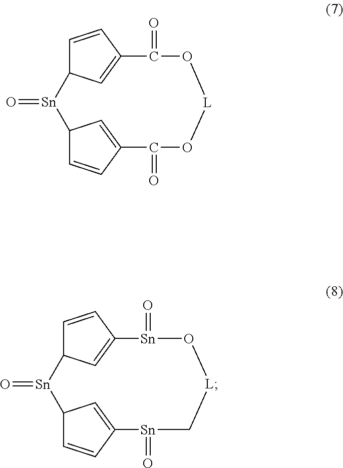

wherein R^{a}, R^{b} are each independently H, —R′, —ER′, —N(R′)₂, —(C═O)OR′, —SnX₃, —Sn(R¹R²R³), —(Sn═O)OR′, —(Sn═O)—O—Sn(R¹R²R³), —E—SnX₃, —E—Sn(R¹R²R³), or —(C═O)—O—Sn(R¹R²R³) as below;

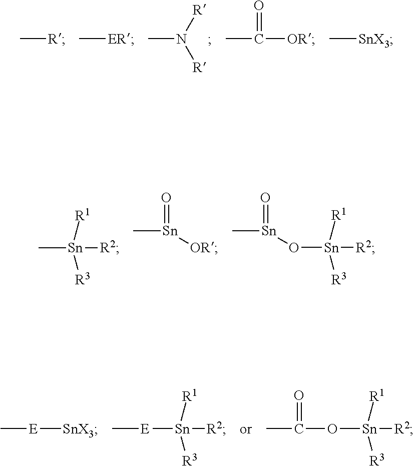

Wherein R^{c}, R^{d}, R^{e} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein E=O, S, Se, or Te; X=F, Cl, Br, or I; L is a substituted or unsubstituted alkylene group with 2 to 20 carbon atoms, or a substituted or unsubstituted aryl group with 6-20 carbon atoms.

Wherein R¹, R², R³ are each independently —R′, —ER′, —N(R′)₂, —O—(C═O)—R′, —(C═O)—R′, —N(R′)—(C═O)—R′, or —(C═O)—N(R′)₂ group as below:

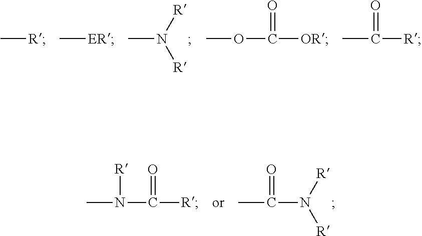

wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; wherein E=O, S, Se, or Te.

In other aspects, the present invention pertains to a method of photolithography patterning, including depositing an organotin photoresist composition over a substrate to form a photoresist layer, wherein the organotin photoresist comprises (stannocenyl oxide)tin compound; exposing the organotin photoresist layer to actinic radiation to form a latent pattern; and developing the latent pattern by applying a developer to remove the unexposed or exposed portion of photoresists to form a photolithography pattern, including wet or dry developer, such as organic solvent or aqueous solution. In some embodiments, the unexposed portions of organotin photoresists may be removed by sublimation or vaporization under reduced pressure, and/or high temperature.

In further aspect, The present invention further pertains to a method of stabilization; wherein an organic additive stabilizes organotin photoresist composition for photolithography patterning. Organic additive stabilization may overcome the disadvantages like poor stability and solubility and/or short shelf time from non-stabilized conventional organotin photoresists. The method of stabilization comprises the addition of organic additive to stabilize the as-formed organotin compounds, particularly organotin clusters or nanoparticles, and to prevent from aggregation occurred or precipitate formation. The aggregation or precipitation can lead to scums or defects on the surface of substrates during photolithography patterning. The organic additives contain various functional groups, such as —SH, —OH, —NH₂, —COOH, —CONH₂, including but not limited to, organic thiol, organic alcohol, organic amine, organic amide, organic carboxylic acid, organic phosphine, phosphine oxide, or phosphonic acid.

In another aspect, the present invention is further to provide an alternative organotin (stannocenyl oxide)tin photoresists with higher resolution, sensitivity, and lower line width roughness without pattern collapse during microelectronic patterning. The photosensitivity, stability, and uniformity of organotin photoresist compositions determine high resolution and efficiency of photolithography. The present invention is to provide improved stability, solubility, uniformity and shelf life of organic molecules stabilized (stannocenyl oxide)tin compound photoresist compositions for substrate surface coating without aggregation, precipitation or age.

In an additional aspect, the invention pertains to a method for (stannocenyl oxide)tin photoresists deposition on a surface of semiconductor substrate by wet deposition like spin-on coating, spray coating, dip coating, vapor deposition, knife edge coating, or dry deposition like chemical vapor deposition, physical vapor deposition, atomic layer deposition, or other approaches.

The invention relates to radiation sensitive (stannocenyl oxide)tin photoresist composition, which can be efficiently patterned after exposure to extreme ultraviolet radiation (EUV), deep ultraviolet radiation (DUV), electron beam radiation, X-ray radiation, or ion-beam radiation, or other likes to form high resolution patterns with low line width roughness, high resolution, low dose and large contrast, such as for <7 nm.

### BRIEF DESCRIPTION OF THE DRAWINGS

FIG. 1 illustrates a flowchart of organotin photoresist radiation photolithography patterning processing on the surface of semiconductor substrate surface.

### DETAILED DESCRIPTION

The present invention pertains to organotin photoresist composition for photolithography patterning, wherein organotin photoresist composition comprises a (stannocenyl oxide)tin compound, a solvent, and/or an additive. Stannocenyl oxide comprises cyclopentadienyl C₅H₅ group, or substituted cyclopentadienyl C₅H₄R, C₅H₃R₂, C₅H₂R₃, C₅HR₄, or C₅R₅ group with hapticity of η¹, η², η³, η⁴, or η⁵ of isomers. The present invention is to provide a method of photolithography patterning of (stannocenyl oxide)tin compound photoresist composition, particularly, suitable for EUV lithography (e.g. <7 nm). The method of photolithography patterning comprises depositing a (stannocenyl oxide)tin compound photoresist composition over a substrate to form a photoresist layer after baking, exposing the photoresist layer to actinic radiation to form a latent pattern; and developing the latent pattern by applying a developer to remove unexposed or exposed portion of photoresists to form a photolithography pattern. The present invention is further to provide a method of stabilization of organotin photoresist by applying organic molecules as additives to stabilize (stannocenyl oxide)tin compounds, particularly clusters. Organic molecules stabilized (stannocenyl oxide)tin compound photoresists may have higher resolution, sensitivity, solubility, stability, shelf life, and lower line width roughness without pattern collapse during microelectronic patterning. The photosensitivity and thermostability of organotin photoresists determine high resolution and efficiency for photolithography patterning.

As described herein, the singular forms “a”, “an”, “one”, and “the” are intended to include the plural forms as well, unless clearly indicated otherwise. Further, the expression “one of,” “at least one of,” “any”, and “selected from,” when preceding a list of elements, modify the entire list of elements and do not modify the individual elements of the list.

As described herein, the terms “includes”, “including”, “comprise”, “comprising”, when used in this specification, specify the presence of the stated features, steps, operations, elements, components, but do not preclude the presence or addition of one or more other features, steps, operations, elements, components, and/or group thereof.

As described herein, the term “and/or” includes any and all combinations of one or more of the associated listed items. Further, the use of “may” when describing embodiments of the present disclosure refers to “one or more embodiments of the present disclosure”.

As described herein, the terms “use,” “using,” and “used” may be considered synonymous with the terms “utilize,” “utilized”, “applied”, respectively. In addition, the terms “about,” “only,” and similar terms are used as terms of approximation and not as terms of degree, and are intended to account for the inherent deviation in measured or calculated values that would be recognized by those of ordinary skill in the art.

The term “alkyl” or “alkyl group” refers to a saturated linear or branched-chain substituted or unsubstituted hydrocarbon of 1 to 20 carbon atoms, e.g., methyl, ethyl, propyl, butyl. The term “alkenyl” refers to an aliphatic hydrocarbon of 2 to 20 carbon atoms containing at least one double bond. The term “alkynyl” refers to an aliphatic hydrocarbon of 2 to 20 carbon atoms containing at least one triple bond. The term “cycloalkyl” refers to cyclic aliphatic hydrocarbon of 3 to 20 carbon atoms, e.g., cyclopropyl, cyclobutyl, cyclohexyl. The term “cycloalkenyl” refers to substituted and unsubstituted cyclic aliphatic unsaturated organic groups of 3 to 20 carbon atoms including at least one double bond hydrocarbon. The term ‘aryl” refers to substituted or unsubstituted aromatic group with 6-20 carbon atoms, e.g., phenyl, benzyl.

In some embodiments, cycloalkenyl group comprises substituted and unsubstituted C4 to C8 cyclic aliphatic unsaturated organic groups including at least one double bond, for example,

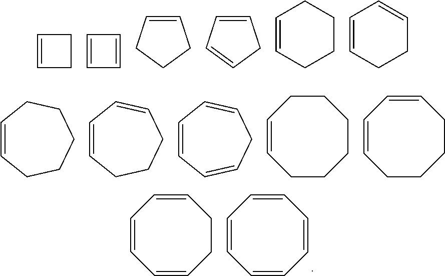

The term “alkylene” refers to a saturated divalent hydrocarbons by removal of two hydrogen atoms from a saturated hydrocarbons of 2 to 20 carbon atoms, e.g., methylene (—CH₂—), ethylene (—CH₂CH₂—), propylene (—CH₂CH₂CH₂—), or the like.

The term “amine” refers to primary (—NH₂), secondary (—NHR), tertiary (—NR₂) amine group. The term “cyclic amine” refers to [R—NH—R′], wherein [R—R′] is cyclic substituted and unsubstituted C3 to C8 organic groups, including, but not limited to:

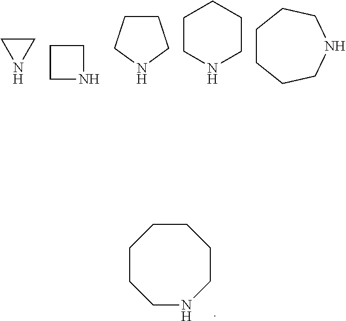

The term “ether” refers to the R—O—R′ group. The term “cyclic ether” refers to the [R—O—R′], wherein [R—R′] is cyclic substituted and unsubstituted C3 to C8 organic groups, e.g.,

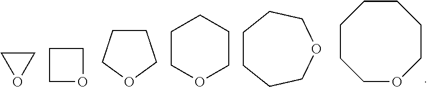

The term “ester” refers to the R—(C═O)—O—R′ group. The term “cyclic ester” refers to the [R—(C═O)—O—R′], wherein [R—R′] is cvclic substituted and unsubstituted C4 to C8 organic groups, e.g.,

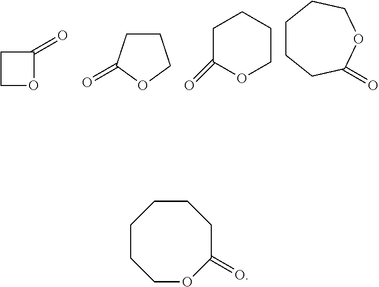

The term “halide” refers to the F, Cl, Br, or I. The term “nitro” refers to the —NO₂. The term “silyl” refers to the —SiR—, —SiR₂—, or —SiR₃ group. The term “thiol” refers to —SH group. The term “thiolate” refers to —SR group. The term “carbonyl” refers to the —C═O group. The term “oxo” refers to —O—, or ═O. In the above described, R, R′ are independently a substituted or unsubstituted alkyl, alkenyl, alkynyl, cycloalkyl, or cycloalkenyl group with 1 to 20 carbon atoms, or a substituted or unsubstituted aryl group with 6-20 carbon atoms.

In the present disclosure, the term “substituted” refers to replacement of a hydrogen atom with a C1 to C20 alkyl group, a C2 to C20 alkene group, a C2 to C20 alkyne group, a C3 to C20 cycloalkyl group, a C6 to C20 aryl group, or other relevant groups, e.g., acid, amide, amine, cyano, ether, cyclic ether, ester, cyclic ester, halide, imine, nitro, silyl, thiol, or carbonyl group, for example, chloroalkyl, fluoroalkyl, fluorobenzyl, trifluoroacetic acid.

The terms “η¹” refers to one carbon atom bonded to one metal atom. The terms “η²” refers to two carbon atoms bonded to one metal atom. The terms “η³” refers to three carbon atoms bonded to one metal atom. The terms “η⁴” refers to four carbon atoms bonded to one metal atom. The terms “η⁵” refers to five carbon atoms bonded to one metal atom.

EUV lithography is under the development for the mass production of next generation <7 nm node. EUV photoresists are required to achieve higher performance, higher sensitivity and resolution, and cost reduction.

EUV light has been applied for photolithography at about 13.5 nm. The EUV light can be generated from Sn plasma or Xe plasma source excited using high energy lasers or discharge pulses.

Organometallic photoresists are used in EUV lithography because metals have high adsorption capacity of EUV radiation. Radiation sensitivity and thermal-, oxygen- and moisture-stability are important for organometallic photoresists. In some embodiments, organometallic photoresists may adsorb moisture and oxygen, which may result in decreasing stability, as well decreasing solubility in developer solutions. In addition, in some embodiments, photoresist layer may outgas volatile components prior to the radiation exposure and development operations, which may negatively affect the lithography performance, pattern collapse and increase defects.

In general, metal central plays the key role in determining the absorption of photo radiation. Tin atom provides strong absorption of extreme ultraviolet (EUV) light at 13.5 nm, therein tin cations can be selected based on the desired radiation and absorption cross section. The organic ligand bonded to tin also has absorption of EUV light. The tuning and modification of organic ligands can change the resolution, sensitivity and radiation absorption, and the desired control of the material properties.

(Stannocenyl oxide)tin compound photoresists comprise cyclopentadienyl group, Sn—C bond, or Sn—O bond, or Sn—S bond, or Sn—Se bond, or Sn—Te bond, or Sn—N bond, or Sn—X bond (X=F, Cl, Br, or I), or Sn—O—Sn bond providing desirable radiation sensitive and stabilization for precursor metal cations. The organotin (stannocenyl oxide)tin compound photoresists possess excellent properties for the application of photolithographic patterning.

Examples of specific organotin photoresists that may be used in implementations of the invention, comprise (stannocenyl oxide)tin compounds represented by Chemical Formulas (1)-(8) as below:

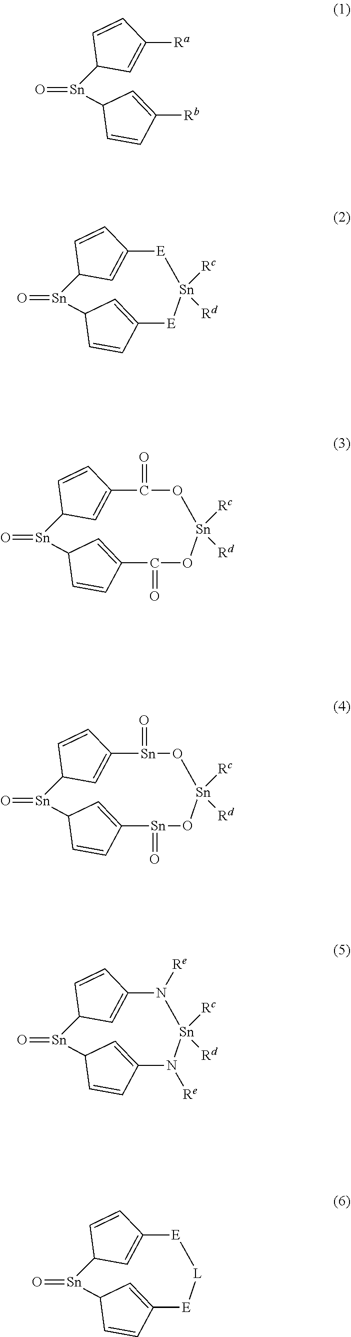

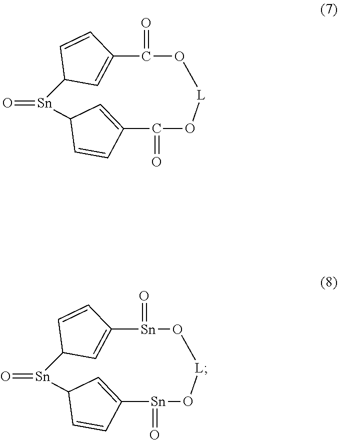

wherein R^{a}, R^{b} are each independently H, —R′, —ER′, —N(R′)₂, —(C═O)OR′, —SnX₃, —Sn(R¹R²R³), —(Sn═O)OR′, —(Sn═O)—O—Sn(R¹R²R³), —E—SnX₃, —E—Sn(R¹R²R³), or —(C═O)—O—Sn(R¹R²R³) depicted as below;

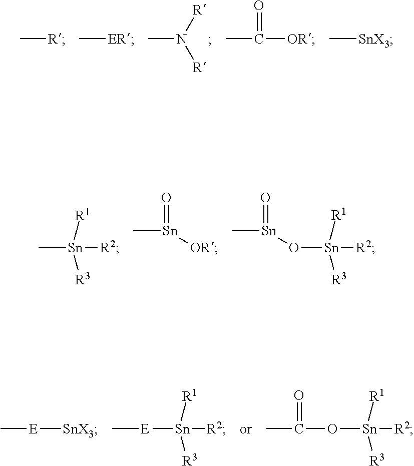

wherein E=O, S, Se, or Te, X=F, Cl, Br, or I;
wherein R¹, R², R³ are each independently —R′, —ER′, —N(R′)₂, —O—(C═O)—R′, —(C═O)—R′, —N(R′)—(C═O)—R′, or —(C═O)—N(R′)₂ group as below:

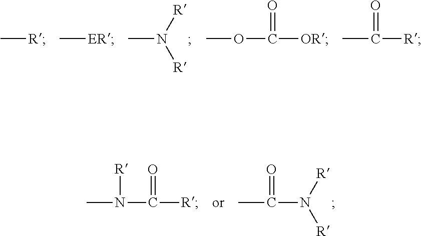

wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te;
wherein R^{c}, R^{d}, R^{e} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein E=O, S, Se, or Te; L is a substituted or unsubstituted alkylene group with 2 to 20 carbon atoms, or a substituted or unsubstituted aryl group with 6-20 carbon atoms.

For example, R′ is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, cyclopentadienyl, phenyl, or benzyl group.

In some embodiments, one of R^{a} or R^{b} is H, which means the (stannocenyl oxide)tin compounds are mono-cyclopentadienyl functionalization comprising the above-described groups. In some other embodiments, R^{a}, R^{b} are not H, rather than each independently groups as above described, which means the (stannocenyl oxide)tin compounds are bis-cyclopentadienyl functionalization comprising the above-described groups.

As one of ordinary skill in the art will recognize, the chemical compounds listed here are merely intended as illustrated examples of (stannocenyl oxide)tin compound photoresists, and are not intended to limit the embodiments to only those (stannocenyl oxide)tin compound photoresists specifically described. Rather, any suitable (stannocenyl oxide)tin compound photoresist may be used, and all such organotin compound photoresists are fully intended to be included within the scope of the present embodiments.

The (stannocenyl oxide)tin compounds represented by Chemical Formulas (1)-(8) contain cyclopentadienyl group, wherein stannocenyl oxide comprises cyclopentadienyl C₅H₅ (Cp) group, or substituted cyclopentadienyl C₅H₄R, C₅H₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group. For example, R is H, a methyl, ethyl, isopropyl, n-butyl, t-butyl, t-amyl, s-butyl, pentyl, hexyl, neopentyl, cyclohexyl, cyclopentyl, cyclobutyl, cyclopropyl, phenyl, or benzyl group.

Cyclopentadienyl C₅H₅ group, or substituted cyclopentadienyl C₅H₄R, C₅H₃R₂, C₅H₂R₃, C₅HR₄, or C₅R₅ group comprises hapticity of η¹, η², η³, η⁴, or η⁵ of isomers.

Stannocenyl oxide comprises hapticity of η¹, η², η³, η⁴, or η⁵ of isomers. For example, in some embodiments, stannocenyl oxide is η¹, or η⁵ hapticity depicted as below;

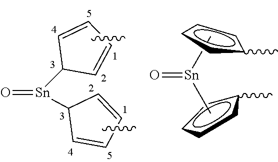

η¹-stannocenyl oxide (left), η⁵-stannocenyl oxide (right);
wherein η¹-stannocenyl oxide comprises 1, or 2, or 3, or 4, or 5-substituted cyclopentadienyl, for example, η¹-1,3-, or 1,4-, or 2,4-cyclopentadienyl; “ [symbol] ” denotes Cp bonding with related functional groups, such as R^{a}, R^{b} as above-described.

In some embodiments, stannocenyl oxide comprises cyclopentadienyl C₅H₅ group, or substituted C₅H₄R, C₅H₃R₂, C₅H₂R₃, C₅HR₄, or C₅R₅ group with hapticity of n⁵ isomers, such as sandwich or half-sandwich compounds bearing π bond. A person of ordinary skills in the art will recognize that the structures of cyclopentadienyl or substituted cyclopentadienyl with hapticity of η¹, η², η³, η⁴, or η⁵ of isomers within the explicit ranges of above are contemplated and are within the present disclosure. For example, mono-substituted η⁵-(stannocenyl) oxides depicted as below:

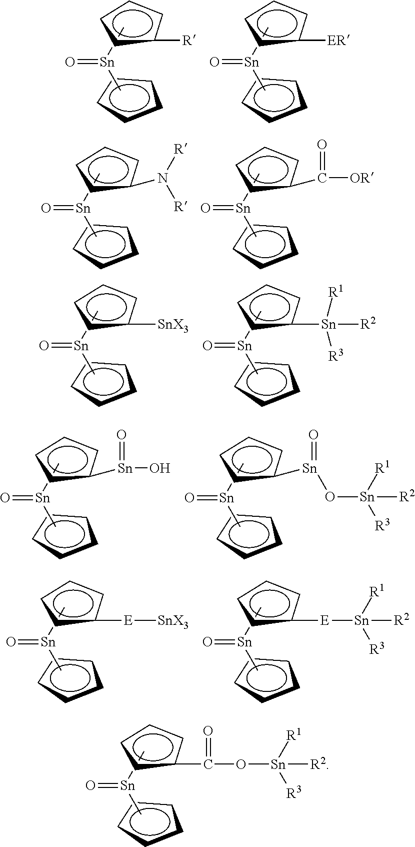

In some embodiments, (stannocenyl oxide)tin compounds may be prepared by reaction of relevant (stannocneyl)tin compounds with oxygen-containing reagents, such as oxygen, ozone, air, hydrogen peroxide, organic peroxide, peroxide acid, or likes under ambient conditions.

Cyclopentadienyl group (C₅R₅, or Cp) may impart photosensitivity to the compounds, and the Cₚ—Sn bond formed may promote suitable solubility in an organic solvent to (stannocenyl oxide)tin compounds. Accordingly, these Cₚ—Sn bond containing (stannocenyl oxide)tin compounds according to an embodiment may have improved sensitivity, resolution and stability, and may suitable for EUV photoresists, and/or the precursors for EUV lithography to form tin oxide or tin oxide hydroxide film.

The (stannocenyl oxide)tin compounds contain cyclopentadienyl-Sn bond (Cₚ—Sn bond). Cₚ—Sn bond is sensitive to UV light and occurs the radiation disruption to generate free radical when exposures to UV light, which has been demonstrated, for example, P. J. Baker, A. G. Davies, M.-W. Tse, “The Photolysis of cyclopentadienyl compounds of tin and mercury. Electron spin resonance spectra and electronic configuration of the cyclopentadienyl, deuteriocyclopentadienyl, and alkylcyclopentadienyl radicals”, Journal of Chemical Society, Perkin II, 1980, 941-948; S. G. Baxter, A. H. Cowley, J. G. Lasch, M. Lattman, W. P. Sharum, C. A. Stewart, “Electronic structures of bent-sandwich compounds of the main-group elements: A molecular orbital and UV photoelectron spectroscopic study of bis(cyclopentadienyl)tin and related compounds”, Journal of the American Chemical Society, 1982, 104, 4064-4069, all of which are incorporated herein by references. Baker, et. al. reported that the UV photolysis of unsubstituted sandwich and half-sandwich cyclopentadienyl-tin (IV) (C₅H₅—Sn) compounds, i.e., C₅H₅SnMe₃, C₅H₅SnBu₃, (C₅H₅)₂SnBu₂, C₅H₅SnCl₃, (C₅H₅)₂SnCl₂, (C₅H₅)₃SnCl, and (C₅H₅)₄Sn in toluene showed strong EPR spectra of the C₅H₅● radical. This study demonstrated cyclopentadienyl (C₅H₅) group or substituted cyclopentadienyl (C₅R₅) group is much more sensitive to UV light compared with alkyl (e.g., methyl, butyl) groups under identical conditions. This property is beneficial to decrease EUV light dose and increase resolution.

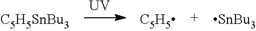

The (stannocenyl oxide)tin compounds contain tin and C—Sn bond, therefore may adsorb extreme ultraviolet light at 13.5 nm.

(Stannocenyl oxide)tin compound photoresists contain cyclopentadienyl (Cp), or substituted-cyclopentadienyl group, π bond, C—Sn bond and related interaction and may have excellent (e.g., suitable) sensitivity to high energy light (e.g., EUV, or DUV) due to tin adsorption high energy EUV ray at 13.5 nm. Accordingly, the related solution compositions may have improved resolution, sensitivity, and stability compared with organic polymer or inorganic photoresists such as metal oxides.

In some embodiments, (stannocenyl oxide)tin compound photoresists may have excellent sensitivity to EUV radiation light due to the tin adsorption high energy EUV ray at 13.5 nm (low expose dose photoresist, e.g., <20 mJ/cm²), and the disruption of Cp—Sn bond to form free radical, tin oxide and relative products, and toughness; low or free pattern defectivity at nanoscale. Accordingly, the solution composition of (stannocenyl oxide)tin compound photoresists may have tight pitch (e.g., <10 nm), and may sustain the yield and deliver high resolution.

The (stannocenyl oxide)tin compound photoresists are soluble in appropriate organic solvents for further photolithography pattern processing. The solution of (stannocenyl oxide)tin compound photoresist can be formed by dissolving in organic solvents, including but not limit to, chloroform, tetrahydrofuran, dimethoxyethane, dimethylformamide, dimethyl sulfoxide, alcohols (e.g., 4-methyl-2-pentenol, ethanol, methanol, propanol, isopropanol, butanol), benzene, toluene, xylene, carboxylic acid, ethers (e.g., tetrahydrofuran, anisole), esters (e.g., ethyl acetate, ethyl lactate, butyl acetate), ketone (e.g., 2-heptanone, methyl ethyl ketone), or two or more mixtures thereof or the like. The solution composition of organotin compounds can be utilized as EUV photoresists for further processing and patterning. A person of ordinary skills in the art will recognize that the choice of solvents and solution composition components within the explicit ranges of above are contemplated and are within the present disclosure.

The organotin photoresist composition may include 0.1 wt % to 60 wt % of the (stannocenyl oxide)tin compounds represented by Chemical Formulas (1)-(8), based on the total weight of the organotin photoresist composition. A person of ordinary skills in the art will recognize that the samples, concentrations, and amounts of (stannocenyl oxide)tin compounds within the explicit ranges of above are contemplated and are within the present disclosure.

The (stannocenyl oxide)tin compound photoresist composition according to embodiments of the present disclosure may have improved etch resistance, sensitivity and resolution, compared with related conventional organic polymer and inorganic resists, wherein oxygen, nitrogen, or various groups are bonded to tin metal as described above.

The (stannocenyl oxide)tin compounds represented by Chemical Formulas (1)-(8) contain Sn—C, or Sn—N, or Sn—O, or Sn—S, or Sn—Se, or Sn—Te, or Sn—X (X=F, Cl, Br, or I) bond with different bond dissociation energy (BDE) and sensitivity to extreme ultraviolet light or like.

In some embodiments, the (stannocenyl oxide)tin compounds represented by Chemical Formulas (1)-(8) may also be used as precursors to prepare organotin photoresists, or organotin photoresist compositions, for example, hydrolysis with water or moisture to form organotin cluster photoresist, or reaction with oxygen sources such as oxygen, air, or hydroperoxide.

In some embodiments, (stannocenyl oxide)tin compounds represented by chemical formulas (1)-(8) may also be used as precursors for condensation reaction with organic acids (e.g., formic acid, acetic acid, citric acid, propionic acid, isovaleric acid, butyric acid, valeric acid, caproic acid, glycolic acid, lactic acid, oxalic acid, or succinic acid) to form organotin photoresists like organotin cluster photoresists, or organotin nanoparticles.

In some embodiments, (stannocenyl oxide)tin compounds represented by chemical formulas (1)-(8) may also be used as precursors for transparent conducting oxides, or thermoelectric materials.

In some embodiments, (stannocenyl oxide)tin compounds as precursors for preparation of organotin photoresists, according to embodiments of the present disclosure, may be represented by at least one of examples. Examples of specific (stannocenyl oxide)tin photoresist materials that may be used in implementations of the invention including but not limited to, oxide hydroxide, alkoxide, amide, anhydride, halide, ester, or oxo, which contain hydrolysable functional groups, such as —OR, —SR, —SeR, —TeR, —X, —N(R)₂, or —OCO.

The radiation sensitive organotin photoresists comprise polynuclear oxo or oxo-hydroxide networks, and alkyl ligands. However, the poor stability of conventional organotin or organotin cluster photoresists in solution after aged would lead to aggregation or precipitation with short shelf life for photolithography, which then would result in scums or defects in photolithography patterning.

In some embodiments, a blend of organotin photoresists with distinct organic ligands provides further improvement in the photolithography patterning, compare with single component organotin compound photoresist.

In some embodiments, the hydrolysable ligands of organotin photoresist precursors carry out hydrolysis with water or moisture from promoting agent to form free hydroxyl (—OH) groups, and then condensation to form organotin clusters. In some embodiments, in situ hydrolysis of organometallic precursors form organometallic dimer represented by (RₙM)₂(OH)₂L₄₋ₙ(H₂O)₂ (M=metal, R=organic ligand). The aggregation of organotin clusters in the presence of organometallic dimer bearing free —OH groups is prevented due to the complete hydrolysis of organometallic dimer. The aggregation of organotin clusters would bridge over proximate resist patterns and then lead to scum.

In some embodiments, a combination of a first precursor (stannocenyl oxide)tin compound and a second precursor (e.g., water, oxygen source, or organic acid) forms photoresist materials over the surface of substrate.

In some embodiments, a hydrolysis promoting agent is required to produce water for promoting completely hydrolysis of organotin compound. Promoting agent can be a high boiling point solvent or a diffusible molecule containing functional groups, for example, acetic acid, butanol, chlorobenzene, cumene, dimethylacetamide (DMAC), dimethyl formamide (DMF), dimethyl sulfoxide (DMSO), hexanol, propionic acid, pyridine, toluidine, toluene sulfonic acid, tetrachloroethane. Diffusible molecules can be represented by the formula R—X, R=an alkyl, cycloalkyl, or aryl group, X=F, Cl, Br, I, —NH₂, —COOH, —OH, —SH, —N₃, —S(═O), imine, ether, ester, aldehyde, ketone, amide, sulfone, acetic acid, cyanide, phosphine, phosphite, aniline, pyridine, pyrrole, alcohol, or polyol.

In some embodiments, an organotin photoresist precursor solution deposits over the surface of substrate or layer to form photoresist layer through in situ hydrolysis with water, or alternative bases like tetramethyl ammonium hydroxide. The baking of the formed photoresist layer at an elevated temperature result in hydrolysis of organometallic compound and subsequent condensation to form organometallic tin oxide hydroxide clusters. After exposure like EUV lithography or e-beam lithography, patterning radiation causes Sn—C bond cleavage and crosslinking of the organometallic tin oxide hydroxide clusters in the exposed portions of photoresists, and then resulted in a stable metal oxide (MOₓ).

In some embodiments, the stability of (stannocenyl oxide)tin photoresists in solution can be improved by organic molecules as stabilizers. The organic molecules-stabilized (stannocenyl oxide)tin photoresists possess improved stability, solubility, uniformity, or shelf life for photolithography patterning.

In some embodiments, organic molecules stabilizers include, but not limited to, organic thiol, organic alcohol, organic amine, organic amide, organic carboxylic acid, organic phosphine, phosphine oxide, phosphonic acid, or a combination thereof.

In some embodiments, organic thiol includes, but not limited to, 1-dodecanethiol, 2-dodecanethiol, 1,12-dodecanedithiol, 1-docosanethiol, 1-decanethiol, 1-heptanethiol, 2-heptanethiol, 1-heptadecanethiol, 1-hexanethiol, 1-hexadecanethiol, 1-nonanethiol, 1-octadecanethiol, 1-octanethiol, 1-pentadecanethiol, 1-tetradecaenthiol, 1-tridecanethiol, 1-undecanethiol, 1,8-octanedithiol, 1,2-ethanedithiol, or a combination thereof.

In some embodiments, organic alcohol includes, but not limited to, 1-dodecanol, 1-octanol, 1-hexadecanol, 1-heptanol, 1-heptadecanol, 1-decanol, 1-undecanol, 1-dodecanol, 1-tridecanol, 1-tetradecaonl, 1-nonaol, 1,10-decanediol, 1,2-hexadecanediol, 1,12-dodecanediol, 1,8-octanediol, 1,11-undecanediol, 2-mercaptoethanol, or a combination thereof.

In some embodiments, organic amine includes, but not limited to, 1-heptadecyloctadecylamine, decylamine, dodecylamine, heptylamine, heptadecylamine, hexadecylamine, isotridecanamine, nonylamine, octadecylamine, octanamine, octylamine, pentadecylamine, tetradecylamine, tridecylamine, triethylamine, undecylamine, undecanamine, 1,8-diaminooctane, 1,9-diaminononane, 1,12-dodecanediamine, 1,11-undecanediamine, or a combination thereof.

In some embodiments, organic amide includes, but not limited to, decanamide, docosanamide, dodecanamide, heanoamide, heptanamide, heptadecanamide, hexadecanamide, icosanamide, nonanamide, nonadecanamide, nonaediamide, octanamide, oleamide, octadecanamide, octanediamide, pentadecanamide, tetradecanamide, tridecanamide, undecanamide, or a combination thereof.

In some embodiments, organic carboxylic acid includes, but not limited to, oleic acid, citric acid, decanoic acid, hexadecanedioic acid, lauric acid, nonanoic acid, octanoic acid, palmitic acid, suberic acid, undecanoic acid, 1,11-undecanedicarboxylic acid, thiolglycolic acid, mercaptoacetic acid, mercaptopropionic acid, or a combination thereof.

In some embodiments, organic phosphine, phosphine oxide, or phosphonic acid, include, but not limited to, trioctylphosphine, tributylphosphine, tris(dimethylamino)phosphine, tris(diethylamino)phosphine, trioctylphospine oxide, hexylphosphonic acid, octadecylphosphonic acid, 11-undecenyl phosphonic acid, or a combination thereof.

In some embodiments, (stannocenyl oxide)tin compound photoresists comprise functional groups, including but not limited to, ether, thiol, silyl, keto, cyano, carbonyl, or halogenated groups, or a combination thereof.

In some embodiments, organic molecules stabilizers may be adsorbed, grafted, immobilized, anchored, or coordinated on (stannocenyl oxide)tin compound photoresists as supports.

The organic molecules stabilized (stannocenyl oxide)tin compound photoresist composition according to an embodiment is prepared by the addition of organic molecular stabilizer to the solution of (stannocenyl oxide)tin compound under ambient condition. The ambient condition includes temperature range from −196 to 300° C., inert N₂ or Ar atmosphere, or air atmosphere, in organic solvent or water with various concentration. The addition of organic molecules stabilizers can be carried out during 0-24 hours after the generation of (stannocenyl oxide)tin compound photoresist solution. A person of ordinary skills in the art will recognize that the temperatures and addition rates within the explicit ranges of above are contemplated and are within the present disclosure.

In some embodiments, the solution composition of (stannocenyl oxide)tin compound photoresists containing cyclopentadienyl or substituted-cyclopentadienyl group, according to embodiments of the present disclosure, may have relatively improved etch resistance, sensitivity and resolution, compared with related conventional organic polymer or inorganic photoresists, wherein oxygen, nitrogen, or various groups are bonded to tin metal as described above.

In some embodiments, the stability, solubility, uniformity, and shelf life of organic molecules stabilized (stannocenyl oxide)tin compound photoresist composition may be improved.

The solution composition of (stannocenyl oxide)tin compound photoresists can be utilized for photolithography patterning including extreme ultraviolet radiation (EUV) (13.5 nm), deep ultraviolet radiation (DUV) such as KrF excimer laser (248 nm) or ArF excimer laser (193 nm), e-beam radiation, X-ray radiation, or ion-beam radiation for further processing and patterning.

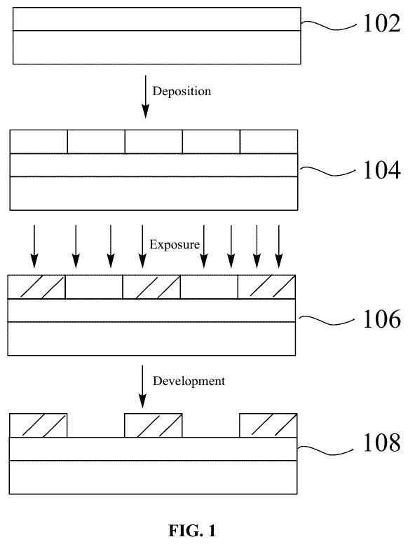

A method of forming photolithography pattern using the organotin photoresist composition is illustrated by FIG. 1.

The general photolithography process described by FIG. 1, is to deposit photoresist over a substrate 102 to form a thin photoresist layer 104; after pre-exposure baking, the formed layer is exposed to actinic radiation to form a latent image 106; after post-exposure baking, the latent is developed by the appropriate developer, such as aqueous basic/acid solutions or organic solvents, to produce the developed resist photolithography pattern 108.

The present invention encompasses organotin photoresist composition for photolithography patterning. Herein organotin includes (stannocenyl oxide)tin compounds represented by Chemical Formulas (1)-(8). The photolithography patterning comprises forming an organotin photoresist composition; wherein the forming the organotin photoresist composition comprises a (stannocenyl oxide)tin compound, a solvent, and/or an additive; (stannocenyl oxide)tin compound photoresist may be stabilized by organic molecules as additives. The formed organotin photoresist composition is then deposited over a substrate such as silicon, silicon oxide to form a photoresist layer. After baking at appropriate temperature, the organotin photoresist layer is exposed to actinic radiation to form a latent pattern. The formed latent pattern is developed by applying a developer to remove the unexposed, or exposed portion of photoresists to form a photolithography pattern.

In some embodiments, the general wet developer compositions can be neutral, basic, acidic aqueous solutions, or organic solvents at low to high concentrations. The temperature for development process can be high or low. The temperature can be applied for the control of the rate or kinetics of development process as required.

In some embodiments, the general wet liquid solvent developer composition comprises an organic solvent blend. Non-limiting examples of organic solvents used in the method of forming patterns according to an embodiment may include, but not limited to, ketones (e.g., acetone, 2-heptanone, methylethylketone, cyclohexanone, 2-pyrrolidone, 1-ethyl-2pyrrolidone, and/or the like), alcohols (e.g., methanol, ethanol, 1-propanol, isopropanol, 1-butanol, 4-methyl-2-propanol, 1,2-propanediol, 1,2-hexanediol, 1,3-propanediol, pentanol, 2-heptanol, and/or the like), esters (e.g., ethyl acetate, n-butyl acetate, butyrolactone, propylene glycol methyl ether, ethylene glycol, propylene glycol, glycerol, ethylene glycol methyl ether, and/or the like), aromatic solvents (e.g., benzene, toluene, xylene), acid (e.g., formic acid, acetic acid, oxalic acid, 2-ethylhexanonic acid), and combinations thereof.

In some embodiments, the wet liquid solvent developing process is applied by dipping the exposed/unexposed substrates into a developer bath. In some embodiments, the wet solvent developing solution can be sprayed into the exposed/unexposed photoresists layer.

In some embodiments, after development the formed pattern coating can be heated to the range of 100-600° C. without pattern collapse. The heat can be carried out under air, inert atmosphere, or in vacuum.

In an embodiment, the actinic radiation is extreme ultraviolet radiation (EUV), or deep ultraviolet radiation (DUV). In another embodiment, the actinic radiation is e-beam radiation, X-ray radiation, or ion-beam radiation.

In an embodiment, organotin photoresists is deposited on a surface of semiconductor substrate by wet deposition like spin-on coating, spray coating, dip coating, or knife edge coating. In another embodiment, organotin photoresist is deposited by chemical vapor deposition (CVD), atomic layer deposition (ALD), or physical vapor deposition.

In some embodiments, after exposure, the exposed and unexposed portion of organotin photoresists possess different chemical and physical properties. Organic ligands of organotin photoresists can be cleaved to form metal oxide or polynuclear oxo/hydroxo network patterns. The unexposed portion of photoresists can be removed by the developer according to different features, solubility and properties. In an embodiment, the developer is a wet developer such as organic solvent, or aqueous solution. In another embodiment, the developer is a dry developer such as Cl₂, CH₂Cl₂, BF₃, BCl₃, CF₄, CCl₄, or HBr. In some embodiments, the developing method is sublimation or vaporization under high reduced pressure in the range of 0.0001 torr to 100 torr, and/or high temperature in the range of 20 to 300° C. A person of ordinary skills in the art will recognize that the reduced pressures and temperatures within the explicit ranges of above are contemplated and are within the present disclosure.

The invention pertains to the methods for preparation and purification of (stannocenyl oxide)tin compounds represented by Chemical Formulas (1)-(8). In some embodiments, all chemical manipulations, including preparation and purification, are performed under an inert atmosphere of purified nitrogen or argon in dry and degassed solvents by employing standard Schlenk techniques. The methods for purification of (stannocenyl oxide)tin compounds comprise distillation, extraction, filtration, recrystallization, column chromatography, coordination and sublimation, or a combination thereof.

In some embodiments, the stability, solubility, and uniformity of organic molecules stabilized (stannocenyl oxide)tin compound photoresist composition may be improved, and dissolution during a photolithography such as EUV or DUV. Accordingly, a photolithography pattern having improved stability, solubility, sensitivity and resolution may be afforded by using of (stannocenyl oxide)tin compound photoresist. Additionally, the as-formed pattern by using of (stannocenyl oxide)tin compound photoresist composition may not form scums and defects.

In addition, (stannocenyl oxide)tin compound photoresist compositions for photolithography patterning according to an embodiment is not necessarily limited to the negative tone image but may be formed to have a positive tone image.

The advantages of (stannocenyl oxide)tin compound photoresist are obvious as above discussed, compared with organic polymer photoresist or inorganic photoresists. However, it will be understood that not all the advantages have been necessarily discussed herein to include all embodiments or examples, other embodiments or examples may offer different advantages.

Hereinafter, the present invention is described in more details through Examples regarding the preparation of (stannocenyl oxide)tin compounds as photoresists or as precursors for organotin photoresist compositions for photolithography patterning. However, the present invention is not limited by the Examples. A person of ordinary skills in the art will recognize that the samples and solution composition components within the explicit ranges of above are contemplated and are within the present disclosure.

It is understood that the above described examples and embodiments are intend to be illustrative purpose only. It should be apparent that the present invention has described with references to particular embodiments, and is not limited to the example embodiment as described, and may be variously modified and transformed. A person with ordinary skill in the art will recognize that changes can be made in form and detail without departing from the spirit and scope of this invention. Accordingly, the modified or transformed example embodiments as such may be understood from the technical ideas and aspects of the present invention, and the modified example embodiments are thus within the scope of the appended claims of the present invention and equivalents thereof.

What is claimed is:

1. An organotin photoresist composition for photolithography patterning, comprising:
a (stannocenyl oxide)tin compound, a solvent, and/or an additive;
wherein (stannocenyl oxide)tin compound is one or more selected from chemical formulas (1)-(8) as below: 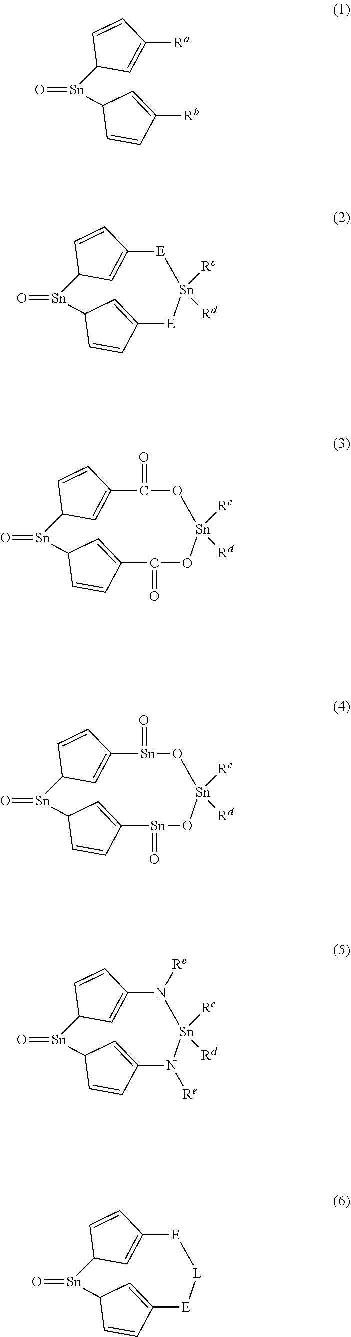 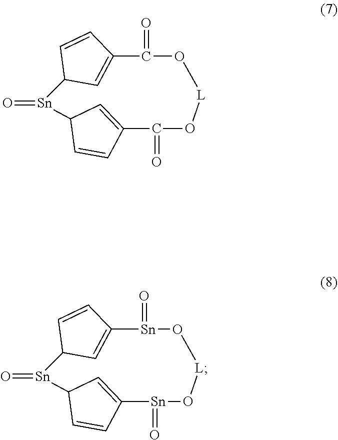
wherein R^{a}, R^{b} are each independently H, or one selected from the group consisting of: 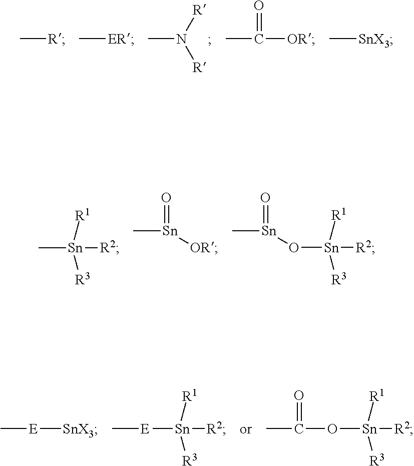
wherein R^{c}, R^{d}, R^{e} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms;
wherein E=O, S, Se, or Te, L is a substituted or unsubstituted alkylene group with 2 to 20 carbon atoms, or a substituted or unsubstituted aryl group with 6-20 carbon atoms.

2. The organotin photoresist composition of claim 1, wherein R¹, R², R³ are each independently —R′, —ER′, —N(R′)₂, —O—(C═O)—R′, —(C═O)—R′, —N(R′)—(C═O)—R′, or —(C═O)—N(R′)₂ group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te, X=F, Cl, Br, or I.

3. The organotin photoresist composition of claim 1, wherein stannocenyl oxide comprises cyclopentadienyl CsHs group, or substituted cyclopentadienyl C₅H₄R, CH₃R₂, C₅H₂R₃, C₅HR₄, or C₅R₅ group, wherein R is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, or an amino, cyano, ether, ester, halide, nitro, silyl, thiol, or carbonyl group.

4. The organotin photoresist composition of claim 1, wherein stannocenyl oxide comprises hapticity of η¹, η², η³, η⁴, or η⁵ of isomers.

5. The organotin photoresist composition of claim 3, wherein R=H, a methyl, ethyl, propyl, n-butyl, t-butyl, or cyclohexyl group.

6. The organotin photoresist composition of claim 1, wherein cycloalkenyl group comprises substituted or unsubstituted C4 to C8 cyclic aliphatic unsaturated organic groups including at least one double bond.

7. The organotin photoresist composition of claim 2, wherein R′ is a methyl, ethyl, propyl, n-butyl, t-butyl, or cyclopentadienyl group.

8. The organotin photoresist composition of claim 1, wherein the additive comprises organic thiol, organic alcohol, organic amine, organic amide, organic carboxylic acid, organic phosphine, organic phosphine oxide, or organic phosphonic acid.

9. The organotin photoresist composition of claim 1, wherein photolithography patterning includes extreme ultraviolet radiation, deep ultraviolet radiation, e-beam radiation, X-ray radiation, or ion-beam radiation.

10. The organotin photoresist composition of claim 1, wherein (stannocenyl oxide)tin compounds represented by chemical formulas (1)-(8) may also be used as precursors for preparation of organotin photoresist, or organotin photoresist composition.

11. A method for photolithography patterning, comprising:
depositing an organotin photoresist composition over a substrate to form a photoresist layer;
wherein the organotin photoresist comprises (stannocenyl oxide)tin compound, wherein the (stannocenyl oxide)tin compound is one or more selected from chemical formulas (1)-(8) as below: 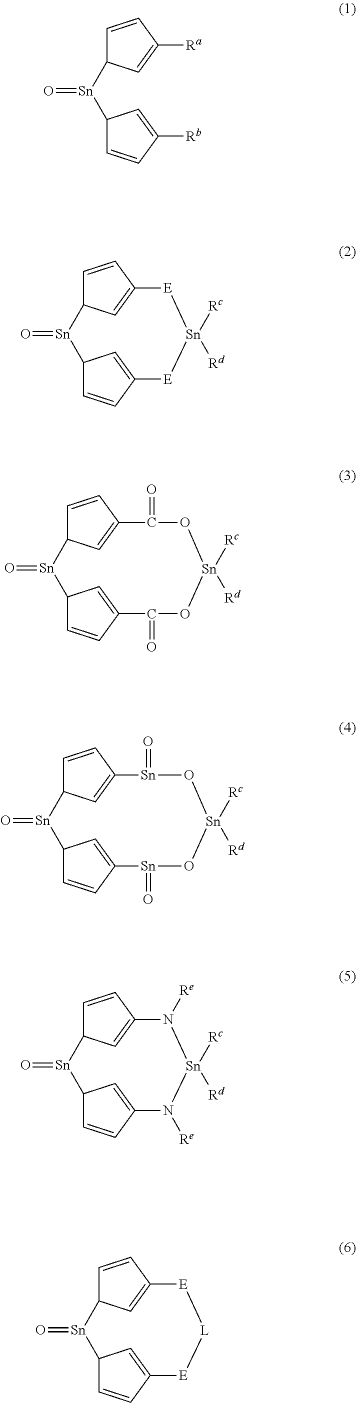 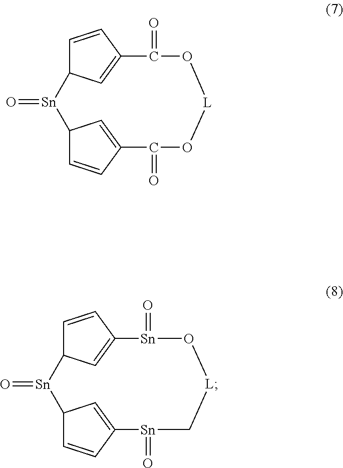
wherein R^{a}, R^{b} are each independently H, or one selected from the group consisting of: 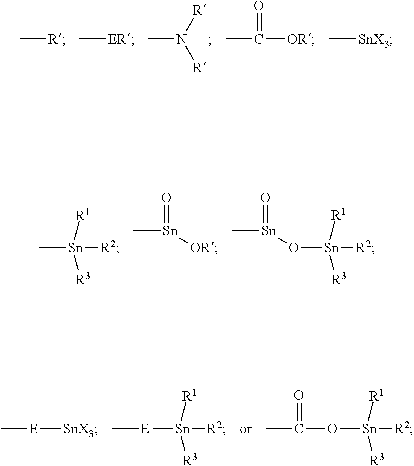
wherein R^{c}, R^{d}, R^{e} are each independently H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms; E=O, S, Se, or Te, L is a substituted or unsubstituted alkylene group with 2 to 20 carbon atoms;
exposing the organotin photoresist layer to actinic radiation to form a latent pattern; and
developing the latent pattern by applying a developer to remove the unexposed or exposed portion of photoresists to form a photolithography pattern.

12. The method of claim 11, wherein R¹, R², R³ are independently —R′, —ER′, —N(R′)₂, —O—(C═O)—R′, —(C═O)—R′, —N(R′)—(C═O)—R′, or —(C═O)—N(R′)₂ group, wherein R′ is H, a substituted or unsubstituted alkyl, alkenyl, alkynyl, cycloalkyl, or cycloalkenyl group with 1 to 20 carbon atoms, or a substituted or unsubstituted aryl group with 6-20 carbon atoms, E=O, S, Se, or Te, X=F, Cl, Br, or I.

13. The method of claim 12, wherein R′ is a methyl, ethyl, propyl, n-butyl, t-butyl, or cyclopentadienyl group.

14. The method of claim 11, wherein R^{c}, R^{d}, R^{e} are each independently a methyl, ethyl, propyl, n-butyl, t-butyl, or cyclopentadienyl group, E=O, X =Cl.

15. The method of claim 11, wherein stannocenyl oxide comprises cyclopentadienyl C₅H₅ group, or substituted cyclopentadienyl C₅H₄R, C₅H₃R₂, C₅H₂R₃, C₅HR₄, or C₅R₅ group.

16. The method of claim 11, wherein stannocenyl oxide comprises hapticity of η¹, or η⁵ of isomers.

17. The method of claim 11, wherein actinic radiation is extreme ultraviolet radiation, or deep ultraviolet radiation.

18. An organotin photoresist, having stannocenyl oxide group represented by chemical formulas (1)-(8) as below: 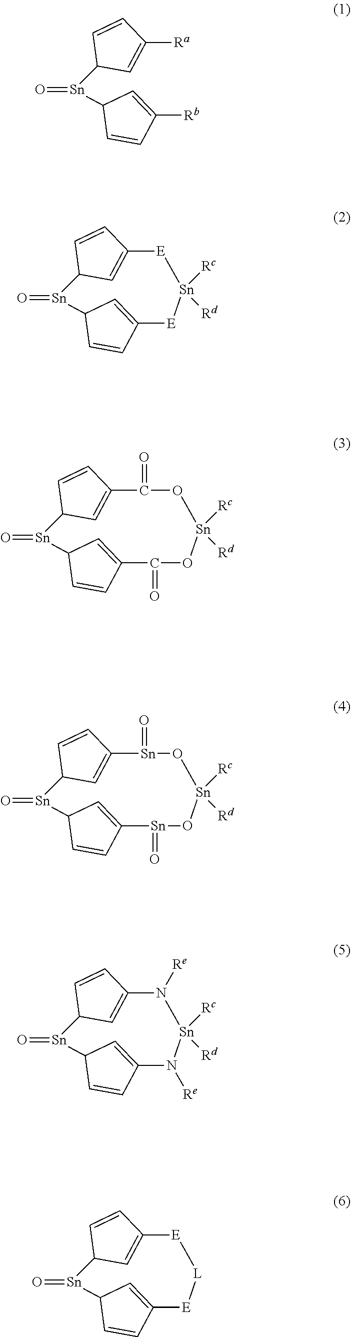 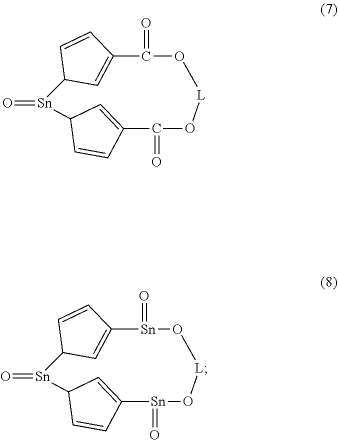
wherein R^{a}, R^{b} are each independently H, or one selected from the group consisting of: 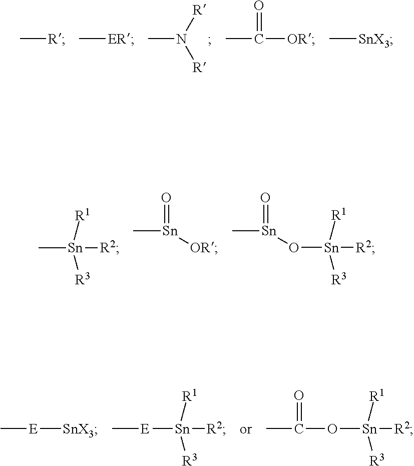
wherein R^{c}, R^{d}, R^{e} are each independently a methyl, ethyl, propyl, n-butyl, t-butyl, phenyl, or cyclopentadienyl group; E=O, S, Se, or Te; L is methylene, ethylene, or propylene; X=Cl.

19. The organotin photoresist of claim 18, wherein R¹, R², R³ are each independently —R′, —ER′, —N(R′)₂, —O—(C═O)—R′, —(C═O)—R′, —N(R′)—(C═O)—R′, or —(C═O)—N(R′)₂ group, wherein R′ is a methyl, ethyl, propyl, n-butyl, t-butyl, or cyclopentadienyl group, E=O, or S.

20. The organotin photoresist of claim 18, wherein stannocenyl oxide comprises cyclopentadienyl C₅H₅, and/or substituted cyclopentadienyl C₅H₄R, C₅H₃R₂, C₅H₂R₃, C₅HR₄, or C₅R₅ group with hapticity of η¹, or η⁵ of isomers, wherein R is H, a methyl, ethyl, propyl, n-butyl, t-butyl, or phenyl group.
